(19) United States
(12) Patent Application Publication
(10) Pub. No.: US 2013/0299869 A1
(43) Pub. Date: Nov. 14, 2013

(54) LIGHT-EMITTING MODULE

(71) Applicant: AU Optronics Corp., Hsin-Chu (TW)

(72) Inventors: Chieh-Jen Cheng, Hsin-Chu (TW); Chia-Hun Cheng, Hsin-Chu (TW)

(21) Appl. No.: 13/945,905

(22) Filed: Jul. 19, 2013

Related U.S. Application Data
(62) Division of application No. 13/162,546, filed on Jun. 16, 2011.

(30) Foreign Application Priority Data
Dec. 24, 2010 (TW) 099145754

(51) Int. Cl. H01L 33/62

(52) U.S. Cl. CPC H01L 33/62
USPC 257/99

(57) ABSTRACT

A light-emitting module includes a light-emitting diode package structure and an insulating support structure. The light-emitting diode package structure includes a package base and at least two leads. The package base has a first surface, and each lead has a bonding surface. The insulating support structure has a second surface and a third surface opposite to each other, and the insulating support structure is disposed under the package base, so that the first surface is in contact with the second surface. The bonding surfaces and the third surface are located in different planes.

### CROSS REFERENCE TO RELATED APPLICATIONS

This application is a divisional application of and claims the benefit of U.S. patent application Ser. No. 13/162,546, filed Jun. 16, 2011.

### BACKGROUND OF THE INVENTION

1. Field of the Invention

The present disclosure relates to a light-emitting module, and more particularly, to a light-emitting module having a light-emitting diode package structure that is horizontally disposed on a circuit board.

2. Description of the Prior Art

Due to having the advantages of the portability, low power consumption, and low radiation, the liquid crystal display has been widely used in various portable information products, such as notebooks, personal data assistants (PDA), etc. The liquid crystal display uses a backlight module to generate light penetrating through liquid crystal molecules with different aligned states so as to display different gray values of an image. Generally, the backlight module is composed of a fluorescent tube and a light guide plate, but the fluorescent tube composed of a cathode ray tube results in environment pollution. Therefore, with a trend toward saving energy and carbon reduction, the fluorescent tube has been gradually replaced by a light bar using light-emitting diodes as light source.

Refer to FIG. 1, which is a schematic diagram illustrating a cross-sectional view of a light bar according to the prior art. As shown in FIG. 1, the light bar 10 includes a plurality of light-emitting diode package structures 12 and a printed circuit board (PCB) 14. Each light-emitting diode package structure 12 has two leads 16 and a light-emitting surface 18, and each light-emitting diode package structure 12 is disposed on the PCB 14. Each light-emitting surface 18 is located at a sidewall of each light-emitting diode package structure 12. In addition, solder paste 20 is disposed between the PCB 14 and each lead 16 and used to fix the light-emitting diode package structure 12 on the PCB 14, and solder paste 20 also electrically connects the light-emitting diode package structure 12 to the PCB 14. In a manufacturing process of the light bar 10, the solder paste 20 is first pasted on bonding pads of the PCB 14, and then, each lead 16 of each light-emitting diode package structure 12 is disposed on a location corresponding to the solder paste 20. Thereafter, the PCB 14 having the light-emitting diode package structure 12 disposed thereon is disposed on a hot plate and passes through a solder pot, so that the solder paste 20 is melt to wrap each lead 16. Finally, the PCB 14 is placed at a room temperature to cool the solder paste 20, and the solder paste 20 is solidified. Accordingly, the bonding pads of the PCB 14 and each lead 16 are combined with the solder paste 20, and the light-emitting diode package structure 12 is fixed on the PCB 14.

However, in the manufacturing process of the light bar, a thickness of the solder paste 20 pasted on each bonding pad is not easily controlled, so that the thicknesses of the solder pastes 20 on different bonding pads are easily different. When the light-emitting diode package structure 12 is disposed on the PCB 14, the light-emitting diode package structure 12 is picked up by a nozzle of a machine and moved onto the bonding pad of the PCB 14, and then, the light-emitting diode package structure 12 is disposed on the bonding pad by the nozzle of the machine. In the process of disposing the light-emitting diode package structure 12, the light-emitting diode package structure 12 is in an inclined state when the leads 16 of the light-emitting diode package structure 12 are respectively disposed on the solder pastes 20 with different thicknesses. For this reason, when the light bar 10 is assembled on a side of the light guide plate in the following process, a part of the light-emitting surface of the light-emitting diode package structure 12 is higher than an upper surface of the light guide plate, so that the assembled backlight module has defective problems of uneven brightness or brightness reduction. Refer to FIG. 2, which is a schematic diagram illustrating a backlight module with uneven brightness according to the prior art. As shown in FIG. 2, the solder pastes 20 disposed between the leads 16 of the light-emitting diode package structure 12 and the PCB 14 have different thicknesses so as to incline the light-emitting diode package structure 12. Thus, a part of the light-emitting surface 18 of the light-emitting diode package structure 12 is higher than the top surface of the light guide plate 22, and a part of light generated from the light-emitting surface 18 directly goes toward the outside and does not enter the light guide plate 22. Accordingly, the situation of uneven brightness is generated.

Therefore, to prevent the light-emitting diode package structure from being inclined to solve the uneven brightness of the backlight module is an objective to be achieved in this field.

### SUMMARY OF THE INVENTION

It is therefore an objective of the present invention to provide a light-emitting module to solve the problem of the uneven brightness of the backlight module.

According to an embodiment of the present invention, a light-emitting module is disclosed. The light-emitting module includes a light-emitting diode package structure and an insulating support structure. The light-emitting diode package structure includes a package base and at least two leads, wherein the package base has a first surface, and each lead respectively has a bonding surface. The insulating support structure has a second surface and a third surface opposite to the second surface, and the insulating support structure is disposed under the package base. The first surface is in contact with the second surface, wherein the bonding surfaces and the third surface are located in different planes.

According to another embodiment of the present invention, a light-emitting module is further disclosed. The light-emitting module includes a light-emitting diode package structure, an insulating support structure, and a circuit board. The light-emitting diode package structure includes a package base and at least two leads, wherein the package base has a first surface, and each lead respectively has a bonding surface. The insulating support structure has a second surface and a third surface opposite to the second surface, and the insulating support structure is disposed under the package base. The first surface is in contact with the second surface. The circuit board has a fourth surface, and the fourth surface is in contact with the third surface of the insulating support structure, wherein the bonding surface of each lead and the second surface of the insulating support structure are spaced a first distance apart, the second surface of the insulating support structure and the fourth surface of the circuit board are spaced a second distance apart, and the first distance is less than the second distance.

According to another embodiment of the present invention, a light-emitting module is further disclosed. The light-emitting module includes a light-emitting diode package structure and a circuit board. The light-emitting diode package structure has a first surface and at least two leads. The circuit board has a passivation layer and a conductive layer, and the passivation layer is disposed on the conductive layer and has two through holes. The through holes expose the conductive layer. The passivation layer has a second surface, and the conductive layer has a third surface opposite to the second surface, wherein the light-emitting diode package structure is disposed between the through holes, so that the first surface is in contact with the second surface, and the leads are electrically connected to the conductive layer respectively.

The present invention disposes the insulating support structure between the package base and the passivation layer, so that the light-emitting diode package structure can be horizontally disposed on the circuit board, and the problem of the uneven brightness resulted form the light-emitting diode package structure being inclined can be solved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a light bar according to the prior art.

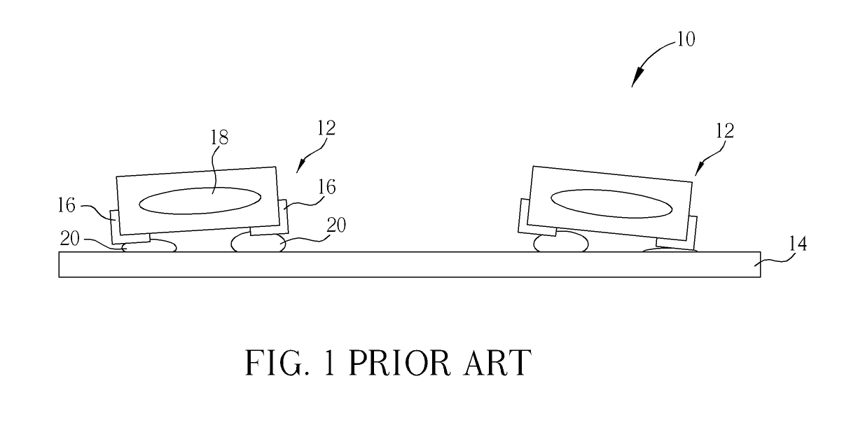

FIG. 2 is a schematic diagram illustrating a backlight module with uneven brightness according to the prior art.

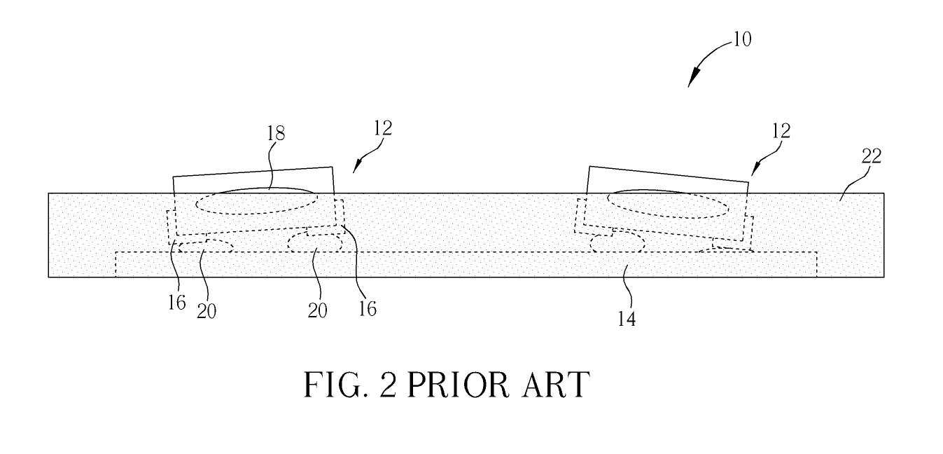

FIG. 3 is a schematic diagram illustrating a cross-sectional view of a light-emitting module according to a first preferred embodiment of the present invention.

FIG. 4 is another example of the light-emitting diode package structure according to the first preferred embodiment of the present invention.

FIG. 5 is another example of the light-emitting diode package structure according to the first preferred embodiment of the present invention.

FIG. 6 is a schematic diagram illustrating a cross-sectional view of a light-emitting module according to a second preferred embodiment of the present invention.

FIG. 7 is a schematic diagram illustrating a light-emitting diode package structure according to the second preferred embodiment of the present invention.

FIG. 8 is a schematic diagram illustrating a cross-sectional view of a light-emitting module according to a third preferred embodiment of the present invention.

FIG. 9 is a schematic diagram illustrating a cross-sectional view of a light-emitting module according to a fourth preferred embodiment of the present invention.

### DETAILED DESCRIPTION

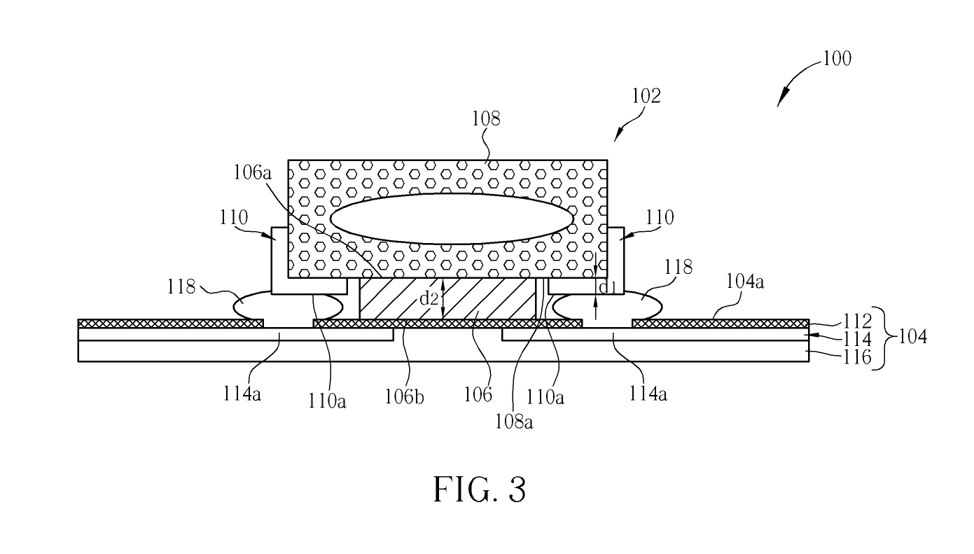

Refer to FIG. 3, which is a schematic diagram illustrating a cross-sectional view of a light-emitting module according to a first embodiment of the present invention. As shown FIG. 3, the light-emitting module 100 of this embodiment includes a light-emitting diode package structure 102 and a circuit board 104. The light-emitting diode package structure 102 of this embodiment is a side view type light-emitting diode package structure, and generates white light, but is not limited to this. The light-emitting diode package structure 102 includes an insulating support structure 106, a package base 108, and at least two leads 110. Each lead 110 is respectively embedded in the package base 108, so that a part of each lead 110 is disposed in the package base 108 and fixed in the package base 108. The other part of each lead 110 is extended from a sidewall of the package base 108, so that each lead 110 respectively has a bonding surface 110a, disposed outside the package base 108 and used to be electrically connected to the outside. The package base 108 has a first surface 108a facing the insulating support structure 106. In this embodiment, each bonding surface 110a is extended to be under the package base 108. In addition, a material of the package base 108 can be an insulating material, such as polyphthalamide (PPA), epoxy resin, glass fiber, titanium oxide, calcium oxide or a combination thereof, but is not limited herein. A material of the leads 110 can be a metal, such as gold, silver, copper, iron, aluminum or an alloy thereof. The light-emitting module of the embodiment is not limited to only have single light-emitting diode package structure 102, and also can have a plurality of light-emitting diode package structures 102.

Furthermore, the insulating support structure 106 has a second surface 106a and a third surface 106b opposite to each other and parallel to each other in this embodiment, and the insulating support structure 106 is disposed under the package base 108 so as to carry the light-emitting diode package structure 102. Moreover, the light-emitting diode package structure 102 is disposed between the leads 110 extended outside the package base 108, so that each bonding surface 110a does not affect the combination of the package base 108 and the insulating support structure 106. Accordingly, the second surface 106a can be in contact with the first surface 108a of the package base 108, and the light-emitting diode package structure 102 can be horizontally fixed on the insulating support structure 106. It should be noted that the bonding surface 110a is not lower than the third surface 106b, and is located above the third surface 106b, so that the bonding surface 110a is located between the second surface 106a and the third surface 106b. In other words, each bonding surface 110a and the second surface 106a are spaced a first distance d1 apart in a vertical direction, and the first surface 108a and the third surface 106b are spaced a second distance d2 apart in the vertical direction. The first distance d1 is smaller than the second distance d2, so that the bonding surface 110a and the third surface 106b are located in different planes. In this embodiment, the insulating support structure 106 is an independent cuboid, and has an upper surface and a lower surface opposite to each other and parallel to each other. Thus, the package base 108 can be horizontally fixed on the insulating support structure 106. The insulating support structure 106 of the present invention is not limited to be cuboid, and also can be a cylinder or a parallelepiped, but is not limited herein. A material of the insulating support structure 106 can be an insulating material, such as epoxy resin or plastic, and is not limited to this.

In addition, the circuit board 104 of the light-emitting module 100 is disposed under the insulating support structure 106, and is used to dispose the insulating support structure 106 carried with the package base 108. Accordingly, the insulating support structure 106 can be disposed between the circuit board 104 and the package base 108. In addition, the circuit board 104 has a fourth surface 104a that is in contact with the third surface 106b of the insulating support structure 106, and thus, the second surface 106b and the fourth surface are spaced the second distance d2 apart. The insulating support structure 106 can be horizontally fixed on the circuit board 104. It should be noted that the second surface 106a and the third surface 106b of this embodiment are parallel to each other, so that the first surface 108a in contact with the second surface 106a can be parallel to the fourth surface 104a in contact with the third surface 106b. Accordingly, the package base 108 can be horizontally disposed on the circuit board 104. The bonding surfaces 110a of the leads 110 are disposed above the third surface 106b, and the first distance d1 is smaller than the second distance d2, so that the bonding surfaces 110a are not in contact with the fourth surface 104a of the circuit board 104 when the package base 108 is disposed on the insulating support structure 108. The circuit board 104 of this embodiment is a printed circuit board, and includes a passivation layer 112, at least one conductive layer 114 and a substrate 116. The conductive layer 114 is disposed on the substrate 116, and the passivation layer 112 is disposed on the conductive layer 114. That is the passivation layer 112 has the fourth surface 104a, but the present invention is not limited to this. The passivation layer 112 exposes a plurality of sections of the conductive layer 114, and each section of the conductive layer 114 can be used as a bonding pad for electrically connecting the conductive glue. The materials of the passivation layer 112 and the substrate 116 can be an insulating material, such as polyimide or epoxy resin, but are not limited herein. In addition, the conductive layer 114 can be composed of conductive material, such as metal, and is not limited to this. Furthermore, the conductive layer 114 of the present invention is not limited to be single layer, and also can be multilayer. The passivation layer 112 can be disposed between the conductive layers 114 so as to electrically insulating the conductive layers 114 from each other.

The light-emitting module 100 further includes two conductive mediums 118, and each conductive medium 118 is respectively in contact with the bonding surface 110a of each lead 110 and the corresponding conductive layer 114 so as to fix each bonding surface 110a on the circuit board 104. Also, each conductive medium 118 electrically connect each lead 110 to the circuit board 104 respectively. In this embodiment, the conductive medium 118 can be solder paste, but is not limited to this. The conductive medium 118 of the embodiment also can be silver glue or silver paste.

As the above-mentioned description, in the light-emitting module 100 of this embodiment, the second distance d2 between the first surface 108a of the package base 108 and the fourth surface 104a of the circuit board 104 is larger than the first distance d1 between each bonding surface 110a of each lead 110 and the first surface 108a of the package base 108 by disposing the insulating support structure 106 between the package base 108 and the circuit board 104. In other words, a vertical distance from the second surface 106a to the fourth surface 104a is larger than a vertical distance from the second surface 106a to the bonding surface 110a, so that the bonding surface 110a and the third surface 106b (the forth surface 104a) are located in different planes. Therefore, in the process of manufacturing the light-emitting module 100 of this embodiment, although the thicknesses of the conductive mediums 118 respectively corresponding to the leads 110 are different, the conductive mediums 118 can be affected by the insulating support structure 106 to have the same thickness due to the conductive medium 118 being colloid, and the light-emitting diode package structure 102 can be horizontally disposed on the circuit board 104. Specifically, when the light-emitting diode package structure 102 has the insulating support structure 106, the first surface 108a, the insulating support structure 106 or bonding surface 110a of the light-emitting diode package structure 102 can be used to limit the conductive medium 118 to have a specific thickness, and the specific thickness usually is a thickness of the insulating support structure 106 or a vertical distance from the bonding surface 110a to the third surface 106b. When the circuit board 104 has the conductive mediums 118 with different thickness disposed thereon, the conductive mediums 118 can be deformed by disposing the light-emitting diode package structure 102, so that the thicknesses of the conductive mediums 118 are limited to be the thickness of the insulating support structure 106. If the light-emitting diode package structure 102 and the insulating support structure 106 are first disposed on the circuit board 104, and then the conductive mediums 118 are disposed, the thicknesses of the conductive mediums 118 are still limited by the insulating support structure 106 and the light-emitting diode package structure 102, and the conductive mediums 118 are formed to have the same thickness. In addition, when the bonding surface 110a is located between the second surface 106a and the third surface 106b, the thicknesses of the conductive mediums 118 is limited by the distance between the bonding surface 110a and the third surface 106b, and the conductive mediums 118 are formed to have the same thickness. Thus, in disposing the light-emitting diode package structure 102, the third surface 106b of the insulating support structure 106 is in contact with and combined with the fourth surface 104a of the circuit board 104. Furthermore, the bonding surface 110a of each lead 110 is not directly in contact with the fourth surface 104a of the circuit board 104, and each conductive medium 118 is in contact with each bonding surface 110a and even warp each bonding surface 110a so as to fix each lead 110 on the circuit board 104 and electrically connect each lead 110 to the circuit board 104. Accordingly, the conductive mediums 118 also can have the same thickness. For this reason, the light-emitting module 100 of this embodiment utilizes the insulating support structure 106 to horizontally dispose the light-emitting diode package structure 102 on the circuit board 104, and the light-emitting diode package structure 102 being inclined can be avoided.

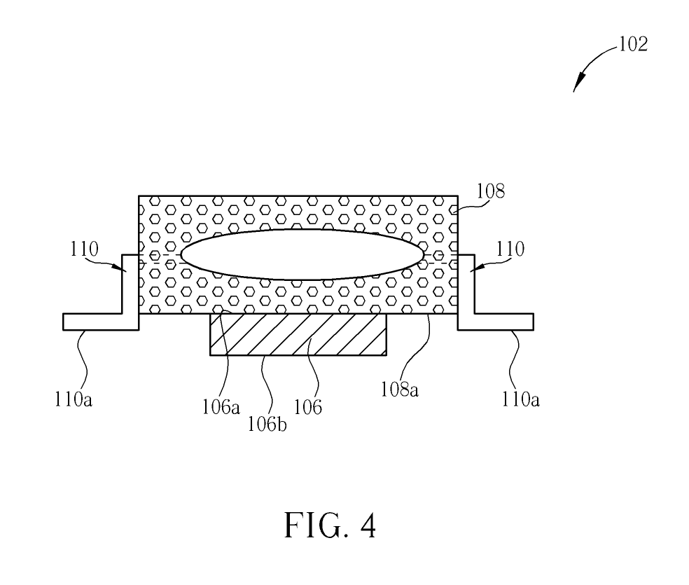

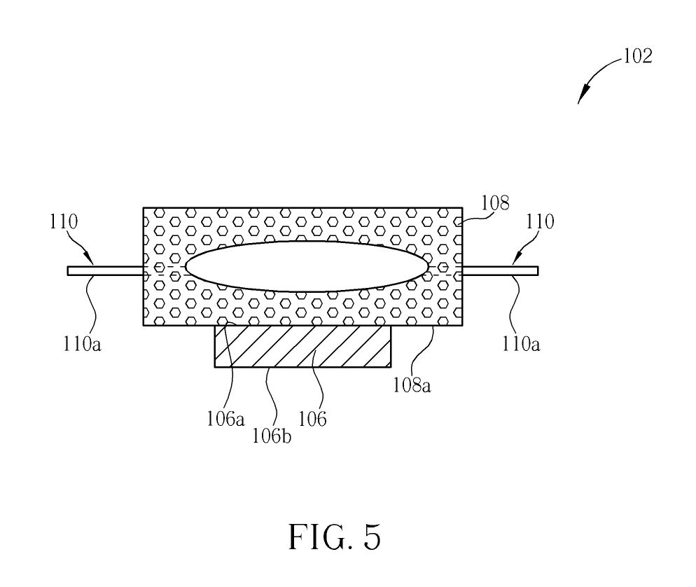

The bonding surfaces of the leads extended from the package base in the embodiment are not limited to be extended to be under the package base. Same elements are denoted by same numerals in the following embodiments, and same structures are not detailed redundantly. Refer to FIG. 4 and FIG. 5. FIG. 4 is another example of the light-emitting diode package structure according to the first preferred embodiment of the present invention, and FIG. 5 is another example of the light-emitting diode package structure according to the first preferred embodiment of the present invention. As shown in FIG. 4, as compared with the above-mentioned first embodiment, each lead 110 in this example is bended downward, and is extended toward the outside of the package base 108. Each lead 110 is not disposed directly under the package base 108, and the bonding surface 110a is disposed between the second surface 106a and the third surface 106b. As shown in FIG. 5, as compared with the above-mentioned first embodiment, each lead 110 in this example is extended toward the outside of the package base 108, and is not bended downward. The bonding surface 110a is disposed above the second surface 106a, so that the second surface 106a can be disposed between the bonding surface 110a and the third surface 106b. The above-mentioned examples only describe the designs of different structures of leads 110, and the structure of leads 110 is not limited herein.

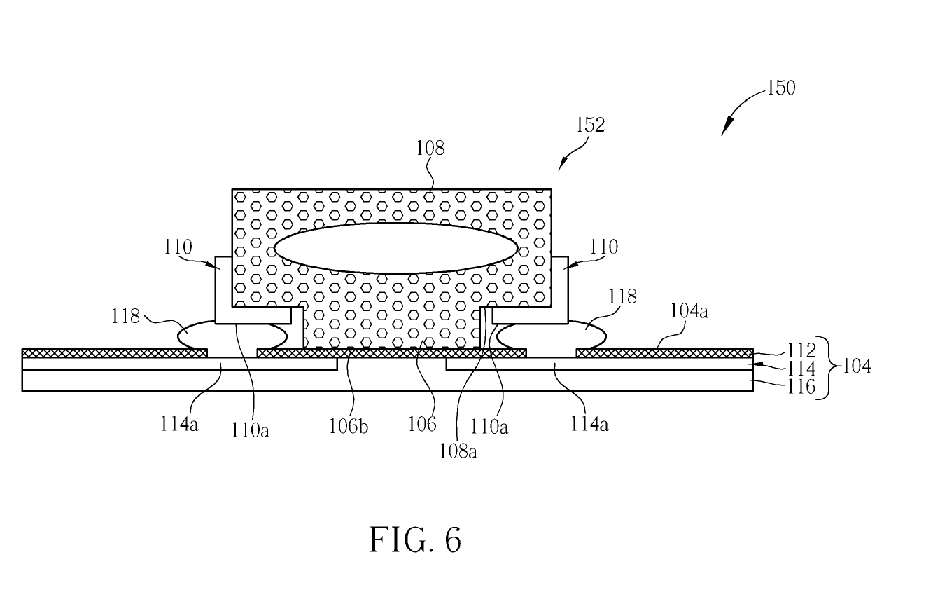

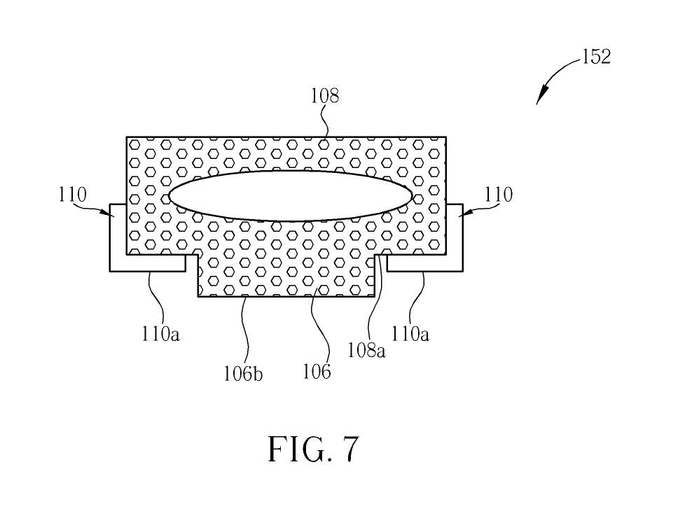

In addition, the insulating support structure in the embodiment is not limited to be an independent structure. Refer to FIG. 6 and FIG. 7. FIG. 6 is a schematic diagram illustrating a cross-sectional view of a light-emitting module according to a second preferred embodiment of the present invention, and FIG. 7 is a schematic diagram illustrating a light-emitting diode package structure according to the second preferred embodiment of the present invention. As shown in FIG. 6, as compared with the light-emitting module of the first embodiment, the insulating support structure 106 of the light-emitting module 150 in this embodiment is a part of the package base 108 protruding downward from the first surface 108a, and the second surface 106a is combined with the first surface 108a. In other words, the package base 108 of this embodiment has a first protruding part used as the insulating support structure 106, and the first protruding part protrudes from the first surface 108a and has the third surface 106b. That is, the insulating support structure 106 and the package base 108 are composed of the same material. Furthermore, the third surface 106b is parallel to the first surface 108a, and the third surface 106b of the first protruding part is in contact with the fourth surface 104a of the circuit board 104, so that the package base 108 can be disposed horizontally on the circuit board 104. In this embodiment, the package base 108 and the insulating support structure 106 are composed of the same material, such as epoxy resin, and are not limited herein. As shown in FIG. 7, according to the light-emitting module of this embodiment, the present invention further provides a light-emitting diode package structure 152. The package base 108 of the light-emitting diode package structure 152 of this embodiment also has the first protruding part used to be the insulating support structure 106. In this embodiment, the insulating support structure 106 can be formed with the package base 108 by an injection molding method, and is not limited to this manufacturing method.

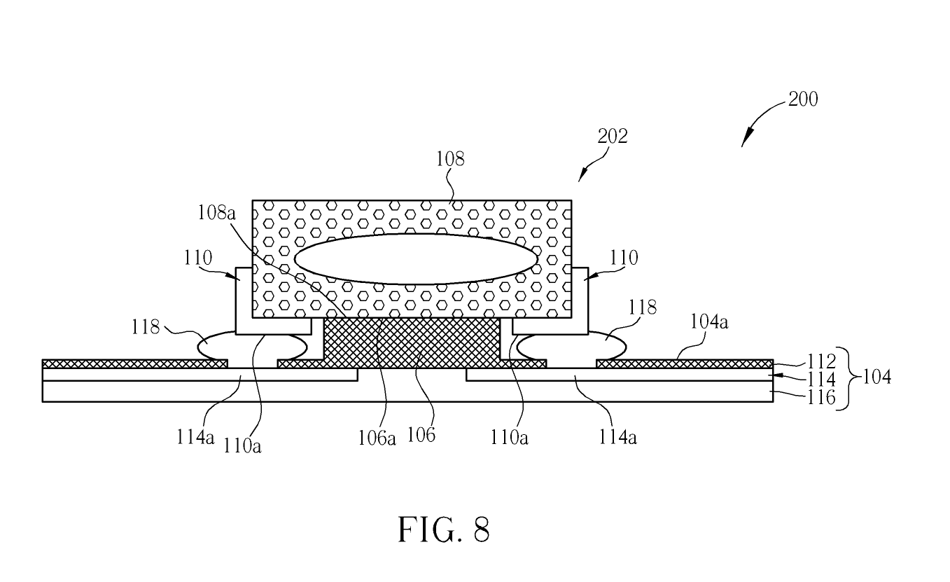

Refer to FIG. 8, which is a schematic diagram illustrating a cross-sectional view of a light-emitting module according to a third preferred embodiment of the present invention. As shown in FIG. 8, as compared with the second embodiment, the insulating support structure 106 of the light-emitting module 200 in this embodiment is separated from the light-emitting diode package structure 202, and is a part of the passivation layer 112 protruding upward from the fourth surface 104a. The third surface 106b of the insulating support structure 106 is combined with the fourth surface 104a of the passivation layer 112. In other words, the passivation layer 112 of this embodiment has a second protruding part, and the second protruding part protrudes from the fourth surface 104a and has the second surface 106a. That is, the insulating support structure 106 and the passivation layer 112 are composed of the same material. In addition, the second surface 106a is parallel to the fourth surface 104a, and the second surface 106a of the second protruding part is in contact with the first surface 108a of the package base 108, so that the light-emitting diode package structure 202 can be horizontally disposed on the passivation layer 112. In this embodiment, the insulating support structure 106 and the passivation layer 112 are composed of a same material, such as epoxy resin, and are limited herein.

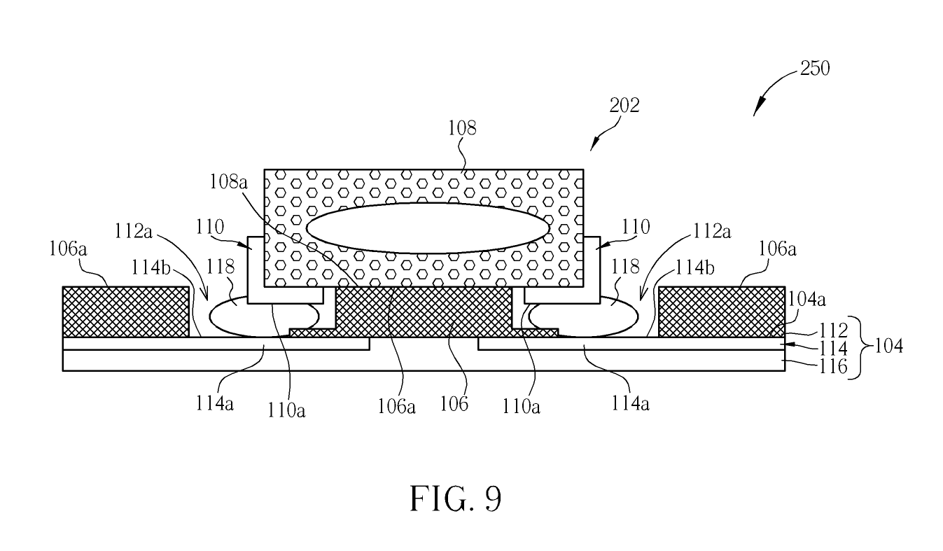

Refer to FIG. 9, which is a schematic diagram illustrating a cross-sectional view of a light-emitting module according to a fourth preferred embodiment of the present invention. As shown in FIG. 9, as compared with the third embodiment, the passivation layer 112 of the light-emitting module 250 in this embodiment has a part without overlapping the light-emitting diode package structure 202, and the part protrudes upward to be located in the same plane as the second surface 106a. In other words, the passivation layer 112 of this embodiment has two through holes 112a, and each through hole 112a exposes the conductive layer 114. The light-emitting diode package structure 202 is disposed between the through holes 112a. Furthermore, the passivation layer 112 has the second surface 106a, and the conductive layer 114 has the third surface 114b, as shown in FIG. 9. The second surface 106a and the third surface 114b are disposed opposite to each other. When the light-emitting diode package structure 202 is disposed between the two through holes 112a, the first surface 108a is in contact with the second surface 106a, and two leads 110 are respectively fixed on the circuit board 104 and electrically connected to the circuit board 104 through the conductive mediums 118. A distance between the third surface 114b and the second surface 106a is larger than the first distance d1 between each bonding surface 110a and the first surface 108a that can also be regarded as the second surface 106a. In this embodiment, the passivation layer 112 between the through holes 112a is the insulating support structure 106, and the first surface 108a of the package base 108 is in contact with the second surface 106a of the passivation layer 112 between the through holes 112a, so that the light-emitting diode package structure 202 can be horizontally disposed on the passivation layer 112. In this embodiment, each conductive medium 118 is respectively disposed in each through hole 112a, and a part of each lead 110 is respectively disposed in each through hole 112a, so that each bonding surface 110a is disposed in each through hole 112a. Each conductive medium 118 is respectively in contact with each bonding surface 110a and the corresponding conductive layer 114, and thus, each bonding surface 110a can be electrically connected to the conductive layer 114 of the circuit board 104 through each conductive medium 118. Furthermore, each bonding surface 110a is not in contact with the surface of the conductive layer 114, so that the combination of the package base 108 and the passivation layer 112 is not affected. Accordingly, the light-emitting diode package structure 202 can be fixed on the circuit board 104, and the conductive layer 114 can be electrically connected to each lead 110. However, the above-mentioned embodiments and figures take the side view type light-emitting diode as an example to describe, but is not limited herein. The present invention also can be applied to a top view type light-emitting diode.

In summary, the present invention disposes the insulating support structure having an upper surface and a lower surface parallel to each other between the package base and the passivation layer, so that the light-emitting diode package structure can be horizontally disposed on the circuit board, and the problem of the uneven brightness resulted form the light-emitting diode package structure being inclined can be solved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light-emitting module, comprising:
a light-emitting diode package structure, comprising a package base and at least two leads, wherein the package base has a first surface, and each lead respectively has a bonding surface; and
an insulating support structure, having a second surface and a third surface opposite to each other, the insulating support structure being disposed under the package base, and the first surface being in contact with the second surface, wherein the bonding surfaces and the third surface are located in different planes, and the package base and the insulating support structure are composed of a same material.

2. The light-emitting module according to claim 1, wherein the insulating support structure is integrally formed with the package base.

3. The light-emitting module according to claim 1, further comprising a circuit board, having a passivation layer, wherein the passivation layer has a fourth surface, and the fourth surface is in contact with the third surface of the insulating support structure.

4. A light-emitting module, comprising:
a light-emitting diode package structure, comprising a package base and at least two leads, wherein the package base has a first surface, and each lead respectively has a bonding surface;
an insulating support structure, having a second surface and a third surface opposite to each other, the insulating support structure being disposed under the package base, and the first surface being in contact with the second surface, wherein the package base and the insulating support structure are composed of a same material; and
a circuit board, having a fourth surface, and the fourth surface being in contact with the third surface of the insulating support structure, wherein the bonding surface of each lead and the second surface of the insulating support structure are spaced a first distance apart, the second surface of the insulating support structure and the fourth surface of the circuit board are spaced a second distance apart, and the first distance is less than the second distance.

5. The light-emitting module according to claim 4, wherein the insulating support structure is integrally formed with the package base.
